(19) United States
(12) Patent Application Publication
(10) Pub. No.: US 2008/0023782 A1
(43) Pub. Date: Jan. 31, 2008

(54) PHOTO SENSOR AND FABRICATION METHOD THEREOF

(75) Inventors: Cha-Hsin LIN, Hsinchu Hsien (TW); Ching-Chiun WANG, Hsinchu Hsien (TW); Lurng-Shehng LEE, Hsinchu Hsien (TW)

Correspondence Address: FULBRIGHT AND JAWORSKI LLP, 555 S. FLOWER STREET, 41ST FLOOR, LOS ANGELES, CA, 90071, US

(73) Assignee: INDUSTRIAL TECHNOLOGY RESEARCH INSTITUTE, Hsinchu Hsien (TW)

(21) Appl. No.: 11/836,080

(22) Filed: Aug. 8, 2007

(30) Foreign Application Priority Data
Jan. 26, 2006 (TW) 095103007

(51) Int. Cl. H01L 31/0232

(52) U.S. Cl. 257/437

(57) ABSTRACT

A photo sensor and a fabrication method thereof are provided. A fluorescent substance is utilized to absorb light in a specific wavelength range and re-emit light detectable by a photo transducer element. An anti-reflective layer is formed on the photo transducer element to reduce refractive scattering of the re-emitting light from the fluorescent substance and focus the re-emitting light on the photo transducer element capable of converting optical signals into electronic signals, thereby measuring the intensity of incident light from circumstances.

### FIELD OF THE INVENTION

The present invention relates to photo sensors and fabrication methods thereof, and more particularly, to a photo sensor made of a silicon material and a fabrication method thereof.

### BACKGROUND OF THE INVENTION

It is known to sense ultraviolet (UV) radiation by photomultiplier-tubes (PMT's). But the PMT's are costly, large size and fragile, and they require high voltage while performing. Moreover, they have broad and long wavelength cut-off, and their wavelength cut-off is not adjustable.

U.S. Pat. No. 4,614,961 to Khan et al. proposes a solid state UV detector of A1ₓGa₁₋ₓN, in which metal organic chemical vapor deposition (MOCVD) is utilized to grow epitaxially(?) A1N and A1ₓGa₁₋ₓN on a sapphire substrate, thereby absorbing and detecting UV light. The A1ₓGa₁₋ₓN material is chosen because it has bandgaps, which lie in the UV range of energy, and because the spectral absorption can be tuned by varying the ratio of aluminum to gallium. Compared with PMT's, the solid state A1ₓGa₁₋ₓN detector is small size, low cost and is not fragile, and has a narrow cut-off wavelength for UV detection. However, due to expensive sapphire substrates (i.e., although sapphire substrates appear to be much smaller than silicon substrates in dimension, their price is much higher than silicon substrates.) and costly MOCVD processes (in spite of mature MOCVD technique), the cost for the aforesaid solid state UV detector is high.

U.S. Pat. No. 6,410,940 to Jiang et al. shows GaN material as an emitting diode or a UV sensor, which comprises an n-type contact, a p-type contact and an optical active component connected between the n-type contact and the p-type contact. If the forward bias is applied to the optical active component, the optical active component may he an emitting diode. If the reverse bias is applied to the optical active component, the optical active component may be an UV sensor. Nevertheless, expensive sapphire substrates are also applied in such UV sensor and the fabrication cost is still high.

Except cost, there are some difficulties if A1ₓGa₁₋ₓN material is used as UV sensors disposed in portable electronic devices. One reason is that A1ₓGa₁₋ₓN has big energy gaps, and thus electrons in valance bands require higher energy in order to be promoted to conduction bands after being radiated. Another reason is that higher voltage needs to be supplied when A1ₓGa₁₋ₓN is applied to a photo sensor, therefore A1ₓGa₁₋ₓN N material is not suitable for portable components.

If a conventional photo sensor of silicon material is used as an ultraviolet photo sensor to detect ultraviolet radiation, the cost may be reduced because of silicon material replacing sapphire substrate and A1ₓGa₁₋ₓN material. However, other spectral response such as visible rays or far infrared rays can also be measured during measuring ultraviolet radiation. Therefore, it is not adequate to directly utilize silicon material as ultraviolet photo sensors.

### SUMMARY OF THE INVENTION

To overcome the above-mentioned problems of the prior art, one object of this invention is to provide a photo sensor and a fabrication method thereof that are composed of silicon material.

Another object of this invention is to provide a photo sensor and a fabrication method thereof that are composed of silicon material, where ultraviolet radiation is detected but visible and infrared rays are not.

A further object of this invention is to provide a photo sensor and a fabrication method thereof for an ultraviolet photo sensor with low cost.

Still another object of this invention is to provide a photo sensor and a fabrication method thereof for disposing in various portable electronic devices.

To achieve the aforementioned and other objects, a fabrication method for a photo sensor according to the present invention is provided, which comprises steps of: providing a photo transducer element on a substrate, wherein the photo transducer element can converter optical signals into electronic signals; forming an anti-reflective layer on the photo transducer element; and coating a fluorescent substance on the anti-reflective layer to absorb light in a specific wavelength range and re-emit light detectable by the photo transducer element.

The present invention also provides a photo sensor, which comprises: a substrate; a photo transducer element provided on the substrate; an anti-reflective layer formed on the photo transducer element; and a fluorescent substance coated on the anti-reflective layer.

Via the fluorescent substance of the photo sensor according to the present invention, merely incident light in a specific wavelength range is absorbed and all incident light except that specific wavelength range cannot be absorbed. So all incident light except that specific wavelength range is filtered by the fluorescent substance, meanwhile the incident light in that specific wavelength range is transformed into light which is adapted to be detected by the photo transducer element. In addition, the anti-reflective layer formed on the photo transducer element can reduce refractive scattering of the transformed light and focus the transformed light on the photo transducer element. Then, optical signals of the transformed light are converted into electronic signals and are measured by the photo transducer element.

### BRIEF DESCRIPTION OF THE DRAWINGS

FIG. 1 is a cross-sectional view showing a photo transducer element provided on a substrate according to one preferred embodiment of this invention;

FIG. 2 is a cross-sectional view showing an anti-reflective layer formed on the photo transducer element according to the preferred embodiment; and

FIG. 3 is a cross-sectional view showing a fluorescent substance coated on the anti-reflective layer according to the preferred embodiment.

### DETAILED DESCRIPTION OF THE PREFERRED EMBODIMENTS

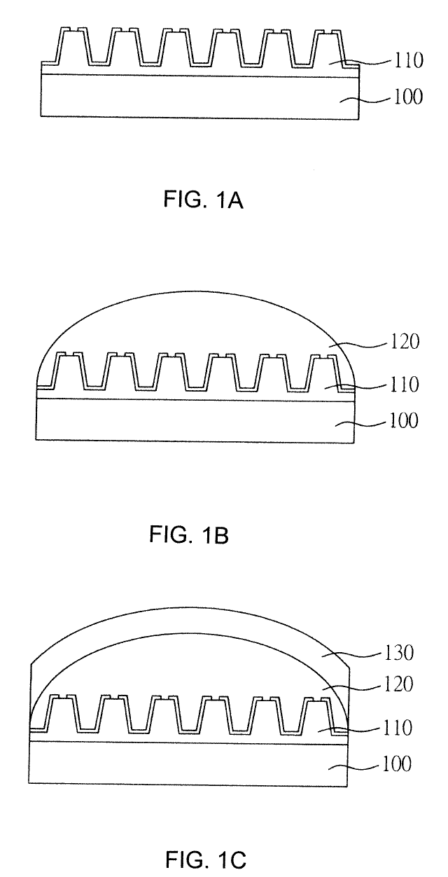

Referring to drawings, the preferred embodiments of the photo sensors and their fabrication methods according to the present invention are illustrated in detail. FIG. 1A to FIG. 1C show a method of fabricating a photo sensor according to the present invention.

Firstly, as shown in FIG. 1A, a photo transducer element 110 is provided on a substrate 100. The photo transducer element 110 converts optical signals into electronic signals. The photo transducer element 110 is one selected from the group consisting of a metal-semiconductor-metal, a positive-intrinsic-negative (PIN) diode, a positive-negative (PN) junction diode, a photoconductor, a Schottky barrier, and the like. In this embodiment, the photo transducer element 110 is the metal-semiconductor-metal and includes a plurality of concaves adapting themselves to various penetrating depth of incoming light in various wavelength ranges, thereby detecting incoming light penetrating more deeply. It should be understood that the photo transducer element 110 of this invention is not limited to those aforementioned and may have different forms depending on the requirements.

Secondly, as shown in FIG. 1B. an anti-reflective layer 120 is formed on the photo transducer element 110. The process for forming the anti-reflective layer 120 is that a substance with a suitable refractive index is deposited on the photo transducer element 110 by a conventional method, and then the deposited substance is etched to become convexes. The convexes allow incoming light to be focused on the photo transducer element 110 and allow refractive scattering of incoming light to be decreased. In this way, signals from the photo transducer element 110 can be prevented from reduction. Because the anti-reflective layer 120 is utilized to avoid scattering of incoming light and to focus incoming light on the photo transducer element 110, the anti-reflective layer 120 is not restricted to the form as shown in FIG. 1B, and the anti-reflective layer 120 may have different types if desired, depending on the photo transducer element 110 or actual requirements.

Finally, as shown in FIG. 1C, a fluorescent substance 130 is coated on the anti-reflective layer 120 according to this invention. The fluorescent substance 130 can absorb light in a specific wavelength range and then re-emit light in another wavelength range detectable by the photo transducer element 110. This approach is based on the character that after the fluorescent substance 130 is excited by photons or electrons, excited higher-energy electrons of the fluorescent substance 130 can relax to their lower-energy ground state, accompanying light emission. As a result, the incident light in a specific wavelength range from circumstances is transformed into light suitable to be measured by the photo transducer element 110. Examples of the fluorescent substance 130 include, but not limited to, Ca₃(PO₄)₃F₁₋ₓC1ₓ:Mn(II) and Sb(III), europium-doped yttrium oxide, terbium-doped lanthanum cerium phosphate and europium-doped barium magnesium aluminum. Because the fluorescent substance 130 can merely absorb light in a specific wavelength range, all incident light except that in this specific wavelength range will be filtered out by the fluorescent substance 130. Accordingly, the fluorescent substance 130 can exclude undesired incident light from circumstances and can allow only incident light in the desired wavelength range to be detected by the photo sensor of this invention.

Furthermore, an anti-reflective layer 120 with suitable refractive index may be chosen depending on the fluorescent substance 130 used. That is, if a different fluorescent substance 130 is applied, the wavelength range of the re-emitting light from the fluorescent substance 130 is also different after the fluorescent substance 130 absorbing incident light in a specific wavelength range from circumstances.

A photo sensor is also provided in the present invention, which comprises: a silicon substrate; a photo transducer element provided on the substrate; an anti-reflective layer formed on the photo transducer element; and a fluorescent substance coated on the anti-reflective layer.

Through the fluorescent substance, the photo sensor of the present invention allows incident light in a specific wavelength range from circumstances to be transformed into light in another wavelength range, which is suitable to be detected by the photo transducer element of this invention. Due to the fluorescent substance just absorbing incident light in a specific wavelength range and not absorbing all incident light except that in this specific wavelength range, all incident light except that in this specific wavelength range will be exclude from the photo sensor and can not be detected by the photo transducer element. Through the convex anti-reflective layer on the photo transducer element, the re-emitting light from the fluorescent substance, such as visible or infrared rays, are focused on the photo transducer element and their refractive scattering is properly reduced and their intensity is measured by the photo transducer element. Under this condition, the intensity of light detected by the photo transducer element is the intensity of the incident light which needs to be measured, i.e., the intensity of light transformed by the fluorescent substance and suitable for the photo transducer element detecting. Therefore, the detection for ultraviolet rays can be achieved according to this invention.

Moreover, the fluorescent substance and the anti-reflective layer formed on the photo transducer element can optionally be varied according to the desired wavelength range measured. Namely, different fluorescent substances can absorb incident light in different specific wavelength range, such as ultraviolet or infrared rays, and transformed such incident light into light detectable by the photo transducer element, then the transformed light focused on the photo transducer element via a suitable anti-reflective layer. The photo sensor of the present invention may be an ultraviolet photo sensor or an infrared photo sensor. The ultraviolet photo sensor can further be a photo sensor for UV-A (380-420 nm), UV-B (320-380 nm), UV-C (100-320 nm) or the like, based on requirements. Because the fluorescent substance is capable of transforming light, it is not necessary to restrain the photo transducer element of conventional expensive material and processes in order to detect the desired wavelength range. That is, the photo transducer element can be made of silicon and the problem of light filtration except ultraviolet rays, induced from the silicon material, can also be solved. Silicon material is used as the photo sensor in this invention, without needing high voltage to be applied, thereby the photo sensor of this invention suitable for mobile electronic devices such as watches, mobile phones, personal digital assistants (PDAs), and the like.

The foregoing detailed descriptions of the embodiments have been discussed for illustrating the features and functions of the present invention and not for limiting the scope of the present invention. Those skilled in the art will appreciate that modifications and variations according to the spirit and principle of the present invention may be made. All such modifications and variations are considered to fall within the spirit and scope of the present invention as defined by the appended claims.

What is claimed is:

1. A fabrication method for a photo sensor, comprising steps of:
providing a photo transducer element on a substrate;
forming an anti-reflective layer on the photo transducer element; and
coating a fluorescent substance on the anti-reflective layer to absorb light in a specific wavelength range and re-emit light detectable by the photo transducer element.

2. The fabrication method according to claim 1, wherein the photo transducer element converts optical signals into electronic signals.

3. The fabrication method according to claim 2, wherein the photo transducer element has a structure of metal-semiconductor-metal.

4. The fabrication method according to claim 3, wherein the photo transducer element has a plurality of concaves adapting themselves to various penetrating depth of the re-emitting light.

5. The fabrication method according to claim 4, wherein deep regions of the concaves accept and detect the re-emitting light penetrating deeply.

6. The fabrication method according to claim 2, wherein the photo transducer element is a positive-intrinsic-negative (PIN) diode.

7. The fabrication method according to claim 2, wherein the photo transducer element is a positive-negative (PN) junction diode.

8. The fabrication method according to claim 2, wherein the photo transducer element is a photoconductor.

9. The fabrication method according to claim 2, wherein the photo transducer element is a phototransistor.

10. The fabrication method according to claim 2, wherein the photo transducer element is a Schottky barrier detector.

11. The fabrication method according to claim 1, wherein the anti-reflective layer is formed on the photo transducer element by depositing a refractive substance on the photo transducer element and thereafter etching the refractive substance to generate convexes.

12. The fabrication method according to claim 11, wherein the anti-reflective layer focuses the re-emitting light on the photo transducer element.

13. The fabrication method according to claim 1, wherein the light in a specific wavelength range absorbed by the fluorescent substance is ultraviolet rays.

14. The fabrication method according to claim 1, wherein the light in a specific wavelength range absorbed by the fluorescent substance is infrared rays.

15. A photo sensor comprising:
a substrate;
a photo transducer element provided on the substrate;
an anti-reflective layer formed on the photo transducer element; and a fluorescent substance coated on the anti-reflective layer.

16. The photo sensor according to claim 15. wherein the photo transducer element converts optical signals into electronic signals.

17. The photo sensor according to claim 15, wherein the anti-reflective layer is convex.

18. The photo sensor according to claim 17, wherein the anti-reflective layer focuses incident light on the photo transducer element.

19. The photo sensor according to claim 15, wherein the fluorescent substance absorbs light in a specific wavelength and re-emits light in another wavelength range.

20. The photo sensor according to claim 19, wherein the light in the specific wavelength range is ultraviolet ray.

21. The photo sensor according to claim 19, wherein the light in the specific wavelength range is an infrared ray.

22. The photo sensor according to claim 19, wherein the re-emitting light in another wavelength are accepted and detected by the photo transducer element.
